(19) United States
(12) Patent Application Publication
(10) Pub. No.: US 2010/0313946 A1
(43) Pub. Date: Dec. 16, 2010

(54) SOLAR CELL MODULE, LAMINATE, AND METHOD FOR PRODUCTION OF SOLAR CELL MODULE

(76) Inventors: Tatsuya Higuchi, Settsu-shi (JP); Kenji Kawasaki, Settsu-shi (JP); Masaji Komori, Settsu-shi (JP); Takayuki Araki, Settsu-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 12/446,515

(22) PCT Filed: Oct. 15, 2007
(86) PCT No.: PCT/JP2007/070080

§ 371 Date: Apr. 21, 2009

(30) Foreign Application Priority Data
Oct. 23, 2006 (JP) 2006-287926

(51) Int. Cl. H01L 31/04; B32B 27/08; C23C 16/50

(52) U.S. Cl. 136/256; 428/422; 427/580

(57) ABSTRACT

Provided is a solar cell module which has a PCTFE film as the light-transmitting surface layer and/or back side protective sheet and is excellent in interlayer adhesion. The invention consists in a solar cell module comprising a light-transmitting surface layer, a solar cell element embedded in a filler and a back side protective sheet, wherein at least one of the light-transmitting surface layer and back side protective sheet is a polychlorotrifluoroethylene film (A) having a treated surface layer obtained by electric discharge treatment in an inert gas containing a reactive organic compound and the treated surface layer is disposed on the solar cell element side.

### TECHNICAL FIELD

The present invention relates to a solar cell module, a laminate and a method of solar cell module production.

### BACKGROUND ART

Conventionally, it is necessary for the surroundings of a solar cell module, which is installed outdoors, to be protected with a protective sheet excellent in weather resistance, moisture resistance, impact resistance and thermal stability, among others. A fluororesin film has so far been suitably used as such a protective sheet. Well known as a general structure of the solar cell module wherein such a fluororesin film is used is a structure comprising a transparent material, such as a glass sheet, disposed on the surface side and serving as a surface supporting member, the fluororesin film disposed on the backside and serving as a backside protective sheet, and a solar cell element embedded in a filler, such as a crosslinked ethylene-vinyl acetate copolymer, and sandwiched therebetween.

However, due to its excellent nonstickiness, a fluororesin has a drawback; namely, the adhesiveness between fluororesin moldings or between a fluororesin molding and another material is poor. Therefore, even when such a solar cell module as mentioned above is formed, it is difficult to maintain their good weather resistance and moisture resistance, among others, due to the insufficient interlaminar adhesion.

Patent Document 1 discloses a solar cell module which comprises, as the protective sheet, a plasma-treated polychlorotrifluoroethylene single-layer sheet or a laminate made of a plasma-treated polychlorotrifluoroethylene sheet, an adhesive layer and a white plastic sheet. However, such a protective sheet delaminates in a high-temperature high-humidity test and can never be one having good durability, although it is excellent in heat resistance at elevated temperatures.

Further, Patent Document 2 discloses a fluororesin molding increased in adhesive strength which comprises a fluororesin film subjected, on one side thereof, to electric discharge treatment using a reactive organic compound and for which a range of a ratio of the number of fluorine atoms to the number of carbon atoms, F/C, and a range of a ratio of the number of oxygen atoms to the number of carbon atoms, O/C, in the fluororesin surface layer are specified. However, this fluororesin molding is not one comprising polychlorotrifluoroethylene (PCTFE).

### [Patent Document 1] Japanese Kokai Publication 2001-127320

### [Patent Document 2] PCT Publication WO 00/20489

### DISCLOSURE OF INVENTION

### Problems which the Invention is to Solve

In view of the above-discussed state of the art, it is an object of the present invention to provide a solar cell module which comprises a PCTFE film as a light-transmitting surface layer and/or a back side protective sheet and has good interlayer adhesiveness.

### Means for Solving the Problems

The present invention is a solar cell module comprising a light-transmitting surface layer, a solar cell element or elements embedded in a filler, and a back side protective sheet, wherein at least one of the light-transmitting surface layer and back side protective sheet is made of a polychlorotrifluoroethylene film (A) having a treated surface layer obtained by electric discharge treatment in an inert gas containing a reactive organic compound and that the treated surface layer is disposed on the solar cell element side.

The present invention is also a solar cell module comprising a light-transmitting surface layer, a solar cell element or elements embedded in a filler, and a back side protective sheet, wherein the back side protective sheet is made of a laminate comprising a polychlorotrifluoroethylene film (A) having a treated surface layer obtained by electric discharge treatment in an inert gas containing a reactive organic compound and a fluorine-free resin sheet (C) and that the treated surface layer is disposed on the fluorine-free resin sheet (C) side.

The present invention is also a laminate which is a laminate comprising a polychlorotrifluoroethylene film (A) having a treated surface layer obtained by electric discharge treatment in an inert gas containing a reactive organic compound and a fluorine-free resin sheet (C), that the fluorine-free resin sheet (C) comprising a polyester resin (C1) and that the treated surface layer is disposed on the polyester resin (C1) side.

The present invention is also a production method of the solar cell module mentioned above, which comprises a step of subjecting a polychlorotrifluoroethylene film (A) to electric discharge treatment in an inert gas containing 0.1 to 3.0% by volume of a reactive organic compound to form a treated surface layer.

In the following, the present invention is described in detail.

The solar cell module according to the invention comprises the PCTFE film (A) as the light-transmitting surface layer and/or the back side protective sheet. By using the PCTFE film (A) as the light-transmitting surface layer and/or the back side protective sheet, it becomes possible for the layer and/or sheet to exhibit good weather resistance and moisture resistance, in particular. Furthermore, the PCTFE film (A) has, on one side thereof, a treated surface layer obtained by electric discharge treatment in the inert gas containing the reactive organic compound and, as a result of the electric discharge treatment, the surface layer of the PCTFE film (A) is improved and provided with good adhesiveness. In the solar cell module of the invention, the PCTFE film (A) is disposed with the treated surface layer thereof facing the solar cell element side; therefore, a high level of adhesiveness can be obtained and good durability can be exhibited even under high temperature and high humidity conditions.

The solar cell module of the invention comprises the light-transmitting surface layer, a solar cell element or elements embedded in the filler, and the back side protective sheet as laminated in that order. In the solar cell module in accordance with a first aspect of the invention, the above-mentioned PCTFE film (A) is used as at least one of the light-transmitting surface layer and back side protective sheet. In each case, the treated surface layer is disposed on the solar cell element side.

The PCTFE film (A) has the treated surface layer only on one side, and the treated surface layer is disposed on the solar cell element side. Thus, by disposing the untreated layer on a side of atmosphere, it becomes possible to obtain good weather resistance and moisture resistance, which are characteristic of the PCTFE film, and, by disposing the treated surface layer on the solar cell element side, it becomes possible to realize firm bonding thereof to the filler. Thus, it becomes possible to attain good durability under high temperature and high humidity conditions and maintain weather resistance and moisture resistance which are required of the protective sheet.

The PCTFE film (A) mentioned above comprising a chlorotrifluoroethylene homopolymer. The use of such homopolymer is required since chlorotrifluoroethylene-based copolymers are inferior in moistureproofness.

The PCTFE film (A) mentioned above has the treated surface layer obtained by electric discharge treatment in an inert gas containing a reactive organic compound. The electric discharge treatment can modify the surface layer of the PCTFE film (A) and improve the adhesiveness thereof.

The reactive organic compound is not particularly restricted provided that it is an oxygen atom-containing polymerizable or non-polymerizable organic compound; there may be mentioned, for example, vinyl esters such as vinyl acetate and vinyl formate; acrylic esters such as glycidyl methacrylate; ethers such as vinyl ethyl ether, vinyl methyl ether and glycidyl methyl ether; carboxylic acids such as acetic acid and formic acid; alcohols such as methyl alcohol, ethyl alcohol, phenol and ethylene glycol; ketones such as acetone and methyl ethyl ketone; carboxylic acid esters such as ethyl acetate and ethyl formate; and acrylic acids such as acrylic acid and methacrylic acid. Among them, vinyl esters, acrylic esters and ketones are preferred from the viewpoint that the modified surface is hardly inactivated (long in life) and from the viewpoint of safety and easy handleability; in particular, vinyl acetate and glycidyl methacrylate are preferred.

The inert gas mentioned above is not particularly restricted but include those generally used in electric discharge treatment. Specifically, there may be mentioned nitrogen gas, helium gas, argon gas and methane gas, among others.

The electric discharge treatment is carried out in a state in which the inert gas and the reactive organic compound occur as a mixture. It is necessary that the reactive organic compound be present in a gaseous (vapor) form in the mixed state.

A concentration of the reactive organic compound in the mixed state is not particularly restricted but may vary according to the reactive organic compound species, among others; however, a concentration of 0.1 to 3.0% by volume is preferred, and a concentration of 0.1 to 1.0% by volume is more preferred.

The electric discharge treatment can be carried out using any of various methods of electric discharge, for example corona discharge, glow discharge and plasma discharge. Corona discharge treatment is preferred from the viewpoint that it is not necessary to reduce the apparatus inside pressure, that it is easy to subject only one side of the film to electric discharge treatment and that the atmosphere gas in the vicinity of the electrodes influences only slightly and stable electric discharge can be attained.

The electric discharge conditions can properly selected according to the reactive organic compound species and concentration, among others. Generally, the electric discharge treatment is carried out at a charge density of 0.3-9.0 W·sec/cm², preferably within the range lower than 3.0 W·sec/cm². As for the treatment temperature, the treatment can be carried out at any temperature level within the range of 0° C. (lower limit) to 100° C. (upper limit).

In a practice of the invention, it is preferred that the PCTFE film (A) be subjected to electric discharge treatment only on one side thereof. When only one side thereof is subjected to electric discharge treatment, the other side can retain the characteristics of the fluororesin.

The method of subjecting only one side thereof to electric discharge treatment is not particularly restricted but there may be mentioned, for example, the method according to which the earth electrode is used in the form of a roll and the PCTFE film (A) is subjected to corona discharge treatment to be contacted with the surface of the roll-shaped earth electrode.

The solar cell module in accordance with the first aspect of the invention comprises the PCTFE film (A) as at least one of the light-transmitting surface layer and back side protective sheet. The PCTFE film (A) is excellent in transparency and impact resistance and therefore serves satisfactorily as the light-transmitting surface layer as well. The solar cell module in accordance with the first aspect preferably comprises the PCTFE film (A) as each of the light-transmitting surface layer and back side protective sheet.

Any of the light-transmitting surface layers known in the art can also be used as the light-transmitting surface layer. The light-transmitting surface layer is not particularly restricted but may be, for example, such a transparent material as a glass sheet.

In the solar cell module mentioned above, the solar cell element or elements, embedded in the filler, is disposed between the light-transmitting surface layer and back side protective sheet. The filler is not particularly restricted but an ethylene-vinyl acetate copolymer [EVA] or the like filler known in the art can be used.

The present invention also relates to a solar cell module comprising a light-transmitting surface layer, a solar cell element or elements embedded in the filler and a back side protective sheet, wherein the back side protective sheet is a laminate comprising the polychlorotrifluoroethylene film (A) having a treated surface layer obtained by electric discharge treatment in the inert gas containing the reactive organic compound and the fluorine-free resin sheet (C), with the treated surface layer disposed on the fluorine-free resin sheet (C) (solar cell module in accordance with a second aspect).

If necessary, the solar cell module in accordance with the second aspect may be provided with an adhesive layer (B) between the polychlorotrifluoroethylene film (A) and fluorine-free resin sheet (C). In particular when a polyethylene terephthalate resin or the like resin poor in adhesiveness to the polychlorotrifluoroethylene film (A) is used as the fluorine-free resin sheet (C), the adhesive layer (B) is preferably provided.

An adhesive constituting the adhesive layer (B) is not particularly restricted but preferably comprises at least one adhesive selected from the group consisting of polyester type adhesives, urethane type adhesives, epoxy type adhesives, nylon type adhesives, ethylene-vinyl acetate type adhesives, acrylic adhesives and rubber type adhesives.

More preferred as the adhesive constituting the adhesive layer (B) from the thermal stability and processability points of view are urethane type adhesives and styrenic rubber type adhesives, among others.

As a fluorine-free resin constituting the fluorine-free resin sheet (C), there may be mentioned, for example, acrylic resins, polycarbonate resins, polyester resins such as polyethylene terephthalate [PET] and polyethylene naphthalate [PEN], polyvinyl chloride, polyamide resins, polypropylene, polyethylene, cyclic polyolefins and styrenic copolymers, among others. Among them, polyester resins are preferred from the weather resistance, impact resistance and heat resistance points of view, and polyethylene terephthalate species are particularly preferred. More preferred among them are heat resistant low oligomer content type polyethylene terephthalate species which are white, high in reflectivity and resistant to hydrolysis.

In the solar cell module according to the invention, a preferred thickness of the PCTFE film (A) varies according to whether the solar cell module is in accordance with the first aspect or the second aspect of the invention. For the solar cell module in accordance with the first aspect, namely when the light-transmitting surface layer and/or back side protective sheet is single-layer form, which is made of the PCTFE film (A) alone, the thickness is preferably 0.025 to 0.5 mm, more preferably 0.05 to 0.3 mm.

For the solar cell module in accordance with the second aspect, namely when the back side protective sheet has the double-layer structure, a thickness of the PCTFE film (A) is preferably 5 to 200 μm. When the thickness is smaller than 5 μm, the handleability may be impaired or the yield may be reduced and, when the thickness is in excess of 200 μm, increases in cost may result. A more preferred lower limit to the above thickness is 12 μm and a more preferred upper limit thereto is 50 μm.

In the solar cell module in accordance with the second aspect, a thickness of the adhesive layer (B) is preferably 1 to 60 μm, more preferably 5 to 40 μm. A thickness of the fluorine-free resin sheet (C) is preferably 30 μm to 0.4 mm, more preferably 50 μm to 0.25 mm. In the case of a single-layer structure as well as in the case of a double-layer structure, the back side protective sheet preferably has a thickness of 0.05 to 0.5 mm, more preferably 0.07 to 0.3 mm.

The thickness of each layer as so referred to herein is a value measured using a microgage.

The present invention further relates to a method of producing the solar cell module in accordance with the first or second aspect. Each of the method of producing the solar cell module in accordance with the first aspect and the method of producing a solar cell module in accordance with the second aspect is characterized by comprising the step of forming a treated surface layer by electric discharge treatment of the polychlorotrifluoroethylene film (A) in the inert gas containing the reactive organic compound. The step of forming the above-mentioned treated surface layer can be carried out in the manner of electric discharge treatment using the above-mentioned reactive organic compound, inert gas and so forth under the conditions mentioned above.

The solar cell module according to the invention can be obtained by piling up the PCTFE film (A) having the treated surface layer as obtained in the above step and the other layers in due order and subjecting the whole to pressure lamination. The solar cell module in accordance with the first aspect can be obtained, for example, by disposing a solar cell element or elements embedded in the filler on a glass sheet to serve as the light-transmitting surface layer, further disposing thereon the PCTFE film (A) to serve as the back side protective sheet and heating the whole under vacuum for pressure lamination.

The solar cell module in accordance with the second aspect can be produced by bonding respective layers together, for example, by the method comprising:

(1) Sandwiching an adhesive layer (B) prepared in advance in the form of a film between a PCTFE film (A) and a fluorine-free resin sheet (C), followed by contact pressure lamination to form a laminate, and disposing a solar cell element or elements embedded in a filer on a glass sheet to serve as the light-transmitting surface layer and further placing thereon the laminate obtained in the above manner, followed by contact pressure lamination by heating under vacuum; or
(2) Applying a coating composition comprising the adhesive onto the treated surface layer side of the PCTFE film (A) and onto the fluorine-free resin sheet (C) and, after drying, subjecting the PCTFE film (A) and fluorine-free resin sheet (C), with the coated faces in contact with each other, to pressure lamination to form a laminate and using the laminate obtained for carrying out the same pressure lamination by heating under vacuum as mentioned above under (1).

The pressure lamination by heating under vacuum can be carried out under conditions properly selected according to the respective layer species employed and the thicknesses thereof, among others; generally, the lamination is carried out preferably at a temperature of 130 to 170° C. The pressure lamination by heating under vacuum is preferably carried out at a pressure of 15 to 10000 Pa.

The pressure lamination by heating under vacuum is generally carried out for 15 to 60 minutes.

The present invention further relates to a laminate which comprises the polychlorotrifluoroethylene film (A) having a treated surface layer obtained by electric discharge treatment in the inert gas containing the reactive organic compound, the adhesive layer (B) and the fluorine-free resin sheet (C), wherein the fluorine-free resin sheet (C) is the polyester resin sheet (C1), with the above-mentioned treated surface layer disposed on the polyester resin (C1) side. The laminate is suitably used as a back side protective sheet for a solar cell module, as mentioned above, and can also be suitably used as a building material waterproof sheet or wallpaper, for instance.

The laminate of the invention can be produced by the means described above referring to the production method of solar cell module.

The solar cell module in accordance with the first or second aspect and the laminate, which are provided by the present invention, are excellent in interlayer adhesive strength. The interlayer adhesive strength so referred to herein is the strength at which the polychlorotrifluoroethylene film (A) is ruptured. For example, a laminate of the invention which comprises the polychlorotrifluoroethylene film (A) and the fluorine-free resin sheet (C), optionally together with the adhesive layer (B) preferably has a adhesive strength of 3 N/cm or higher. When the interlayer adhesive strength is within the above range, the laminate, when used outdoors as a solar cell-protecting sheet or a building material sheet, for instance, can exhibit sufficient durability.

The laminate of the invention is excellent in weathering resistance and, even after 1000 hours of accelerated weathering testing under the conditions mentioned later herein, can maintain at least 85% of the interlayer adhesive strength before accelerated weathering testing. The interlayer adhesive strength so referred to herein is the value obtained by measurement according to ASTM D 882 using a universal material testing machine, RTC-1225A, manufactured by Orientec Co. Ltd.

### EFFECTS OF THE INVENTION

The present invention can provide the solar cell module excellent in interlayer adhesion, having good weather resistance and capable of maintaining moistureproofness.

### BEST MODES FOR CARRYING OUT THE INVENTION

The following examples illustrate the present invention in further detail. These examples are, however, by no means limitative of the scope of the invention. In the examples, “part(s)” and “%” mean “part(s) by mass” and “% by mass”, respectively, unless otherwise specified.

### Example 1

While nitrogen gas containing 0.3% by volume of vinyl acetate was passed through a corona discharge apparatus in the vicinity of the discharge electrode and roll-shaped earth electrode thereof (60° C.), the 0.025-mm-thick PCTFE film was continuously passed therethrough while being contacted with the surface of the roll-shaped earth electrode for one-side corona discharge treatment.

Then, a two-pack urethane type adhesive (product of Toyo Ink Mfg. Co., Ltd.; 15 parts of an ester type base resin, 1 part of an isocyanate type curing agent) was applied to the treated side of the treated PCTFE film to a thickness of 10 μm and, on the adhesive layer obtained, there was disposed a 188-μm-thick PET film (product of Toray Industries, Inc., X10S), and the whole was subjected to lamination at 70° C. The laminate obtained was subjected to 1000 hours of high-temperature, high-humidity testing (85° C.×85%); the levels of adhesive strength before and after testing were measured according to the adhesive strength measuring method mentioned hereinabove for durability evaluation. The results are shown in Table 1. The adhesive strength before testing was 4.0 N/cm, while the adhesive strength after testing was 3.5 N/cm; the decrease in adhesive strength was thus slight. The so-called cohesive failure of the adhesive layer, with the adhesive layer remaining on both the PCTFE film and PET film, was found before as well as after testing.

### Example 2

The laminate was formed and the durability thereof was evaluated in the same manner as in Example 1 except that glycidyl methacrylate was used in lieu of vinyl acetate. The results are shown in Table 1.

### Example 3

The laminate was formed and the durability thereof was evaluated in the same manner as in Example 1 except that a styrenic rubber type adhesive (product of Hitachi Kasei Polymer Co., Ltd.; Hibon YA211-2) was used as the adhesive and that the lamination temperature was lowered to 25° C. The results are shown in Table 1.

### Example 4

The laminate was formed and the durability thereof was evaluated in the same manner as in Example 1 except that the 0.4-mm-thick ethylene-vinyl acetate copolymer (product of Mitsui Chemicals Fabro, Inc., Solar EVA) was used as the counterpart film and that the lamination was carried out by 30 minutes of heating at 150° C. using a vacuum heating laminator. The results are shown in Table 1. Before and after high-temperature, high-humidity testing, the levels of adhesive strength were so high that the PCTFE film was ruptured.

### Example 5

The laminate was formed and the durability thereof was evaluated in the same manner as in Example 1 except that the 0.1-mm-thick PCTFE film was used in lieu of the 0.025-mm-thick PCTFE film and that glycidyl methacrylate was used in lieu of vinyl acetate. The results are shown in Table 1.

### Comparative Examples 1-4

Laminates were formed and evaluated for durability in the same manner as in Example 1 or 3 except that the PCTFE film was treated on one side thereof by corona treatment without using any reactive organic compound, by plasma treatment using a mixed gas composed of argon and hydrogen according to the method described in Japanese Kokai Publication S59-217731 or by plasma treatment using ammonia according to the method described in Japanese Kokai Publication H04-349672. The results are shown in Table 1. Before testing, the laminates obtained were comparable in adhesive strength to the laminates obtained in the examples but, after testing, they could be readily delaminated and thus scarcely retained their initial adhesion strength.

### Comparative Examples 5-9

Laminates were formed and evaluated for durability in the same manner as in Example 4 except that the PCTFE film was treated on one side thereof by corona treatment without using any reactive organic compound, by plasma treatment using a mixed gas composed of argon and hydrogen according to the method described in Japanese Kokai Publication S59-217731 or by plasma treatment using a mixed gas composed of helium and oxygen, a mixed gas composed of helium and methane, or ammonia according to the method described in Japanese Kokai Publication H04-349672. The results are shown in Table 1. The laminates other than the laminate of Comparative Example 5 in which corona treatment was carried out without using any reactive organic compound and the laminate of Comparative Example 9 in which plasma treatment was carried out using ammonia were low in adhesive strength before testing and could be delaminated with ease after testing. Similarly, the laminates of Comparative Example 5 and Comparative Example 9 also showed marked decreases in adhesive strength after testing.

TABLE 1

| | | | | | | | Durability under high | |
|---|---|---|---|---|---|---|---|---|
| | Surface treatment method | | | | | | temperature and high | |
| | Electric | Reactive | | | | Lamination | humidity conditions | |
| | discharge | organic | | Counterpart | | temperature | Before | |
| | treatment | compound | Gas | substrate | Adhesive | (° C.) | testing | After testing |
| Example 1 | Corona | Vinyl acetate | Nitrogen | PET | Urethane type | 70 | 4.0 | 3.5 |
| Example 2 | Corona | Glycidyl | Nitrogen | PET | Urethane type | 70 | 3.8 | 3.3 |
| | | methacrylate | | | | | | |
| Example 3 | Corona | Vinyl acetate | Nitrogen | PET | Styrenic type | 25 | 7.2 | 5.4 |
| Example 4 | Corona | Vinyl acetate | Nitrogen | EVA | — | 150 | Film rupture | Film rupture |
| Example 5 | Corona | Glycidyl | Nitrogen | EVA | — | 150 | Film rupture | Film rupture |
| | | methacrylate | | | | | | |
| Comparative | Corona | — | — | PET | Urethane type | 70 | 3.6 | 0.2 |
| Example 1 | | | | | | | | |
| Comparative | Corona | — | — | PET | Styrenic type | 25 | 7.0 | 2.0 |
| Example 2 | | | | | | | | |
| Comparative | Plasma | — | Argon + Hydrogen | PET | Urethane type | 70 | 3.1 | 0.2 |
| Example 3 | | | | | | | | |
| Comparative | Plasma | — | Ammonia | PET | Urethane type | 70 | 4.8 | 0.5 |
| Example 4 | | | | | | | | |
| Comparative | Corona | — | — | EVA | — | 150 | 5.0 | 0.1 |
| Example 5 | | | | | | | | |
| Comparative | Plasma | — | Argon + Hydrogen | EVA | — | 150 | 0.5 | 0.1 |
| Example 6 | | | | | | | | |
| Comparative | Plasma | — | Helium + Oxygen | EVA | — | 150 | 0.3 | 0.1 |
| Example 7 | | | | | | | | |
| Comparative | Plasma | — | Helium + methane | EVA | — | 150 | 0.5 | 0.1 |
| Example 8 | | | | | | | | |
| Comparative | Plasma | — | Ammonia | EVA | — | 150 | Film rupture | 2.4 |
| Example 9 | | | | | | | | |

From Table 1, it was indicated that the laminates according to the invention have good adhesive strength before testing and show only slight decreases in adhesive strength even after testing. On the other hand, the laminates obtained in the comparative examples were low in adhesive strength already before testing or, even when, before testing, they were comparable in adhesive strength to the laminates obtained in the examples but, after testing, they showed marked decreases in adhesive strength.

### INDUSTRIAL APPLICABILITY

The solar cell module of the invention, which has the constitution described hereinabove, is excellent in weather resistance, moisture resistance and durability and can be used in a stable manner for a long period of time. The laminate of the invention, which has the constitution described hereinabove, can be suitably used not only as a protective sheet in a solar cell module but also as a building material waterproof sheet or wallpaper, among others.

### BRIEF DESCRIPTION OF THE DRAWINGS

FIG. 1 This figure is a representation, in cross section, of an example of the solar cell module according to the invention.

FIG. 2 This figure is a representation, in cross section, of another example of the solar cell module according to the invention.

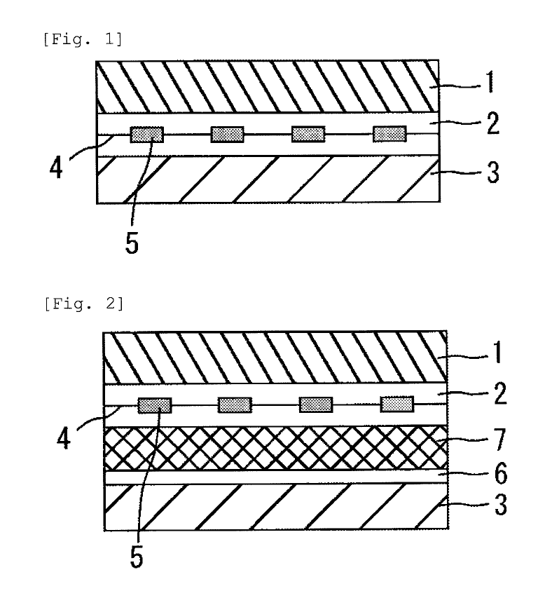

### EXPLANATION OF SYMBOLS

1-Light-transmitting surface layer
2-Filler
3-Back side protective sheet
4-Connecting wire
5-Solar cell element
6-Adhesive layer
7-Fluorine-free resin sheet

1. A solar cell module comprising a light-transmitting surface layer, a solar cell element embedded in a filler, and a back side protective sheet,
at least one of the light-transmitting surface layer and the back side protective sheet being a polychlorotrifluoroethylene film (A) having a treated surface layer obtained by electric discharge treatment in an inert gas containing a reactive organic compound and
the treated surface layer being disposed on the solar cell element side.

2. A solar cell module comprising a light-transmitting surface layer, a solar cell element embedded in a filler, and a back side protective sheet,
the back side protective sheet being a laminate comprising a polychlorotrifluoroethylene film (A) having a treated surface layer obtained by electric discharge treatment in an inert gas containing a reactive organic compound and a fluorine-free resin sheet (C) and
the treated surface layer being disposed on the fluorine-free resin sheet (C) side.

3. The solar cell module according to claim 1,
wherein the reactive organic compound is vinyl acetate and/or glycidyl methacrylate.

4. The solar cell module according to claim 1,
wherein the filler is an ethylene/vinyl acetate copolymer.

5. A laminate
comprising a polychlorotrifluoroethylene film (A) having a treated surface layer obtained by electric discharge treatment in an inert gas containing a reactive organic compound and a fluorine-free resin sheet (C),
the fluorine-free resin sheet (C) comprising a polyester resin (C1) and
the treated surface layer being disposed on the polyester resin (C1) side.

6. A production method of the solar cell module according to claim 1,
which comprises the steps of forming a treated surface layer in a polychlorotrifluoroethylene film (A) subjecting to electric discharge treatment in an inert gas containing 0.1 to 3.0% by volume of a reactive organic compound.
